(19) United States
(12) Patent Application Publication
(10) Pub. No.: US 2026/0039117 A1
(43) Pub. Date: Feb. 5, 2026

(54) CHARGE-STATE CALCULATION DEVICE

(71) Applicant: HITACHI, LTD., Tokyo (JP)

(72) Inventors: Toru KOUNO, Tokyo (JP); Jun TSUNODA, Tokyo (JP); Eri ISOZAKI, Tokyo (JP); Keito AKIZUKI, Tokyo (JP); Naoki YOSHIDA, Tokyo (JP)

(21) Appl. No.: 19/101,975

(22) PCT Filed: Mar. 3, 2023
(86) PCT No.: PCT/JP2023/008013

§ 371 Date: Feb. 7, 2025

(30) Foreign Application Priority Data
Sep. 13, 2022 (JP) 2022-144965

(51) Int. Cl. H02J 3/38; G01R 31/382; H02J 3/00; H02J 3/32

(52) U.S. Cl. CPC H02J 3/38; G01R 31/382; H02J 3/004; H02J 3/32; H02J 2300/24

(57) ABSTRACT

It is an object of the present invention to provide a technology allowing for correct determination of a charge-state that a storage battery has to retain in a self-consignment system based on a weather prediction. A charge-state calculation device according to the present invention determines a charge-state of a storage battery so as to compensate for shortage with discharge from the storage battery even if an actual power generation amount of the solar cell is less than a predicted power generation amount during a power transmission period in which the weather is predicted to have the largest variation range and the largest variation frequency of the solar radiation amount (FIG. 9).

### TECHNICAL FIELD

The present invention relates to a technology of determining a charge-state to be secured by a storage battery when transmitting power generated by a power generation system constituted by a solar cell and the storage battery between bases via a power transmission network.

### BACKGROUND ART

Self-consignment means that a company or the like having a power generation installation uses a power grid owned by a power company when transmitting power generated by the power generation installation between bases. To carry out the self-consignment, it is required to submit a power transmission plan to a management organization (e.g., Organization for Cross-regional Coordination of Transmission Operators: OCCTO) no later than starting of the consignment (e.g., on the day before). Furthermore, while the self-consignment is performed, it is required to transmit power as planned in advance for every predetermined time interval (e.g., 30 minutes). If an actual power transmission deviates from advance planning (imbalance), a penalty is generally imposed.

Patent Literature 1 listed below describes, in view of “providing a power monitoring control device capable of self-consigning surplus power according to its planned value,” a technology of “the power monitoring control device (10) including an actual value determination unit (14) that determines whether an actual consignment value in a period of a predetermined consignment period has reached an actual value upper limit threshold value, and a control unit (16) that performs a consignment suppressing control on a target equipment if the actual consignment value in the period of the consignment period has reached the actual value upper limit threshold value” (see Abstract).

Patent Literature 2 listed below describes, in view of “providing a reasonable evaluation technique for a minimum capacity of an equipped storage battery and an optimal charge/discharge control logic for a small-capacity storage battery in consideration of occurrence of a prediction error involved in a solar radiation amount prediction technology and a storage battery management technology,” a technology of “a power storage installation management device 1 including a charge/discharge plan formulation unit 2 that specifies a consignment time zone generated from a surplus power prediction value based on a power demand prediction value predicted by referencing a predetermined database 5 and a power generation prediction value of which power being generated from renewable energy, that divides, when the consignment time zone extends over a plurality of units of time, the plurality being more than a predetermined value, the consignment time zone into a plurality of time divisions consisting of the units of time, that formulates a charge/discharge plan for a power storage installation so that consignment power may be constant with respect to each time division, and that stores the formulated charge/discharge plan in a predetermined memory unit 4” (see Abstract).

Japanese Patent Application No. 2021-128374 describes a technology of learning a correspondence between solar radiation amount prediction data and detailed weather classification, though it is not related to the self-consignment.

### CITATION LIST

### Patent Literature

Patent Literature 1: Japanese Unexamined Patent Application Publication No. 2021-141769
Patent Literature 2: Japanese Unexamined Patent Application Publication No. 2020-058141

### SUMMARY OF INVENTION

### Technical Problem

Assume a case in which a power generation system that generates power to be transmitted by self-consignment is constituted by, for example, a solar cell and a storage battery. In order to transmit power conforming to advance planning while the self-consignment is performed, if the power generated by the solar cell is less than a consignment scheduled power, it is required to compensate for the power shortage with discharged from the storage battery.

The output power from the solar cell varies depending on the solar radiation amount. There are many different variation patterns of the solar radiation amount depending on the weather, such as a case in which the weather varies largely in a day, a case in which the solar radiation amount is relatively stable, and the like. Accordingly, the output power from the solar cell also presents many different variation patterns such as a case of a large variation and a relatively stable case depending on the weather. Thus, a charge capacity (State Of Charge: SOC) which the storage battery should retain to be compliant with the consignment scheduled power also varies largely depending on the weather. Prior-art consignment technology has not fully considered correctly determine a required charge-state of the storage battery that may largely vary as described above.

The present invention was made in view of the above-described problem, and it is an object of the present invention to provide a technology allowing for correct determination of a charge-state that a storage battery has to retain in a self-consignment system based on a weather prediction.

### Solution to Problem

A charge-state calculation device according to the present invention determines a charge-state of a storage battery so as to compensate for shortage with discharge from the storage battery even if an actual power generation amount of the solar cell is less than a predicted power generation amount during a power transmission period in which the weather is predicted to have the largest variation range and the largest variation frequency of the solar radiation amount.

### Advantageous Effects of Invention

The charge-state calculation device according to the present invention allows for correct determination of a charge-state that a storage battery has to retain in a self-consignment system based on a weather prediction. Objects, configurations, and effects other than the above will be apparent from the description of the following embodiments.

### BRIEF DESCRIPTION OF DRAWINGS

FIG. 1A shows an example configuration of a power generation system owned by a company that performs self-consignment.

FIG. 1B shows an example configuration of a power generation system owned by a company that performs self-consignment.

FIG. 2 is a schematic diagram showing how the self-consignment is performed between bases.

FIG. 3 illustrates an imbalance of power transmission.

FIG. 4 shows an example of weather codes provided by a weather information provider.

FIG. 5A shows a comparison between an actual solar radiation amount on a certain day and solar radiation amount prediction data.

FIG. 5B shows a comparison between an actual solar radiation amount on another day and solar radiation amount prediction data.

FIG. 6 is a schematic diagram showing a procedure in which a power control device 1 learns detailed weather classification.

FIG. 7 illustrates a procedure of estimating the detailed weather classification using the result of learning in the procedure in FIG. 6.

FIG. 8 is a graph comparing an actual consignment with a consignment prediction when the weather code is 12.

FIG. 9 is a flowchart describing a procedure of calculating an SOC that can secure consignment scheduled power with the weather code 12.

FIG. 10 is a graph comparing an actual consignment with a consignment prediction when the weather code is 11.

FIG. 11 is a flowchart describing a procedure of calculating an SOC that can secure consignment scheduled power with the weather code 11.

FIG. 12 is a graph comparing an actual consignment with a consignment prediction when the weather code is 21.

FIG. 13 is a flowchart describing a procedure of calculating an SOC that can secure consignment scheduled power with the weather code 21.

FIG. 14 is a graph comparing an actual consignment with a consignment prediction when the weather code is 10 or 20.

FIG. 15 is a flowchart describing a procedure of calculating an SOC that can secure consignment scheduled power with the weather code 10 or 20.

FIG. 16A shows an example of a user interface provided by the power control device 1.

FIG. 16B shows an example of a user interface provided by the power control device 1.

### DESCRIPTION OF EMBODIMENTS

### First Embodiment

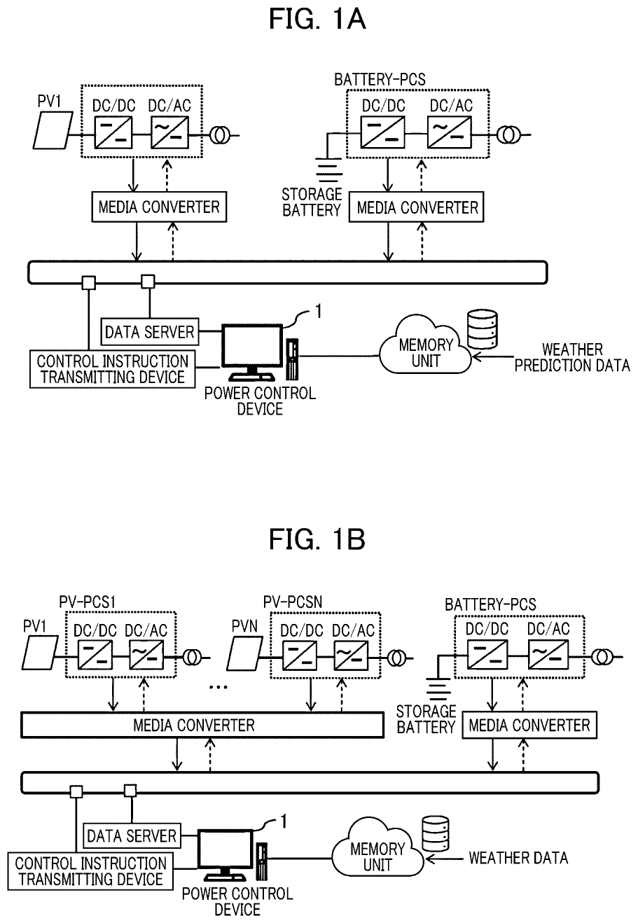

FIGS. 1A and 1B show an example configuration of a power generation system owned by a company that performs self-consignment. The power generation system is constituted by a solar cell (PV) and a storage battery (battery). The solar cell is connected to a power grid via a DC-DC converter and a DC-AC converter. The same applies to the storage battery. A power control device 1 controls operations of the solar cell and the storage battery, respectively, by transmitting an operation instruction to a driving device of the solar cell and a driving device of the storage battery (respectively constituted by the above-described converters). There may be arranged both a plurality of solar batteries and a plurality of storage batteries.

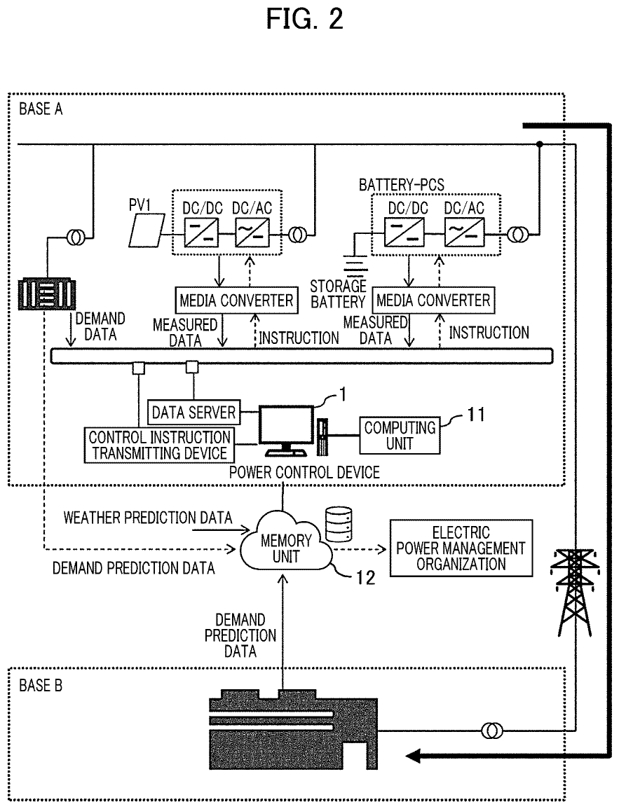

FIG. 2 is a schematic diagram showing how the self-consignment is performed between bases. A base A includes the power generation system described in FIG. 1 and transmits the power generated at the base A to a base B via the power grid. The power control device 1 (charge-state calculation device) controls the power transmission based on demand prediction data, measured data of each installation, and the like according to a procedure described later. The power control device 1 includes a computing unit 11 and a memory unit 12. They will be described later.

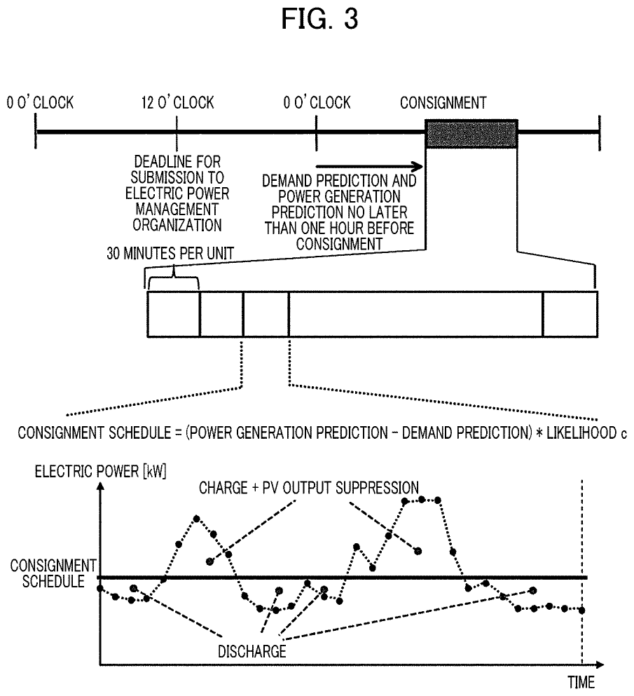

FIG. 3 illustrates an imbalance of power transmission. The company submits a consignment plan describing consignment scheduled power in units of 30 minutes, for example, to an electric power management organization no later than performance of the self-consignment (e.g., on the day before). The consignment scheduled power is calculated by, for example, subtracting a demand prediction from a power generation amount prediction by the power generation system and multiplying the result by a coefficient (≤1.0). The coefficient is for the power generation system to reserve extra operational power, which is referred to as likelihood in this embodiment. By instructing the solar cell to generate power as indicated by the result of multiplying the likelihood, the solar cell shall operate at an operating point at which smaller power than a maximum power point is output.

When actual generated power exceeds the consignment scheduled power, the excess is balanced by suppressing the output power of the solar cell below the maximum power point and also charging the storage battery. When the actual generated power is less than the consignment scheduled power, the shortage is supplemented by discharging the storage battery.

To calculate the consignment scheduled power, it is required to predict the power to be generated by the solar cell and further to predict power demand. Remainder of the subtraction of the demand prediction from the power generation prediction is to be transmitted between the bases as the consignment power. When the power generation prediction is less than the demand prediction, it is required to supplement the shortage by discharging the storage battery. Therefore, the storage battery needs to retain the charge-state enough to be able to secure the consignment scheduled power in a period of performing consignment.

However, the power generation amount of the solar cell has many different variation patterns such as a case of a large variation and a relatively stable case depending on the weather. Therefore, in the present invention, solar radiation amount prediction data in a consignment performing period is obtained from a weather information provider or the like and the weather in the consignment performing period is predicted using the same. Furthermore, an SOC that can secure the consignment scheduled power is calculated in advance with respect to each of the predicted weather. In the following, a technique to predict the weather is described first, and then a procedure of determining the SOC with respect to each predicted weather is described.

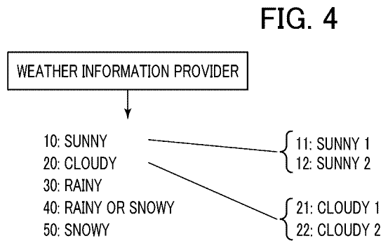

FIG. 4 shows an example of weather codes provided by a weather information provider. The weather codes are generally provided in a large classification such as 10 to 50 shown in FIG. 4. The present invention goes one step further and the weather is classified more finely. For example, a sunny weather is classified into two detailed weather codes 11 to 12.

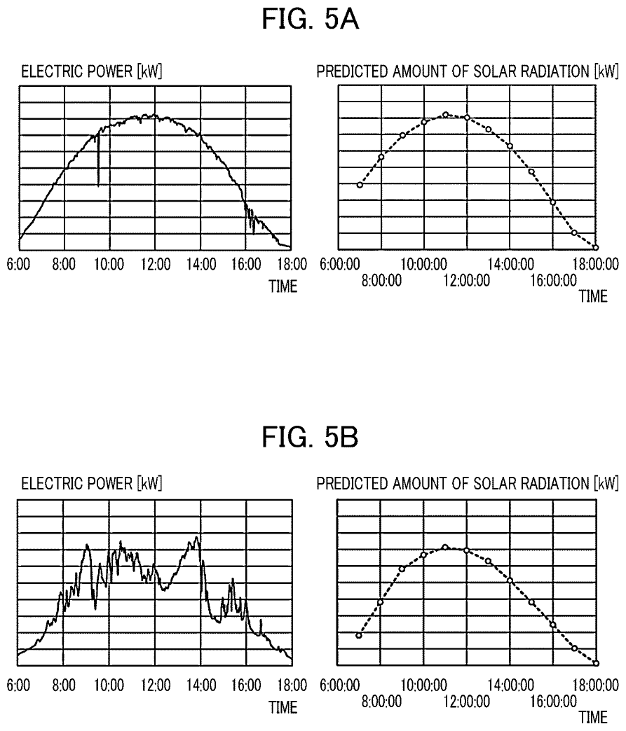

FIG. 5A shows a comparison between an actual solar radiation amount on a certain day and solar radiation amount prediction data. This graph shows an example of one day when the weather code is 10 (sunny). It can be seen from this example that the actual solar radiation amount and the solar radiation amount prediction data match relatively well.

FIG. 5B shows a comparison between an actual solar radiation amount on another day and solar radiation amount prediction data. This graph shows an example of another day when the weather code is 10 (sunny). Although this example uses the same weather code 10 (sunny) as in FIG. 5A, it can be seen that there is a large deviation between the actual solar radiation amount and the solar radiation amount prediction data. In this manner, the solar radiation amount may possibly deviate largely from the prediction data despite the same weather code.

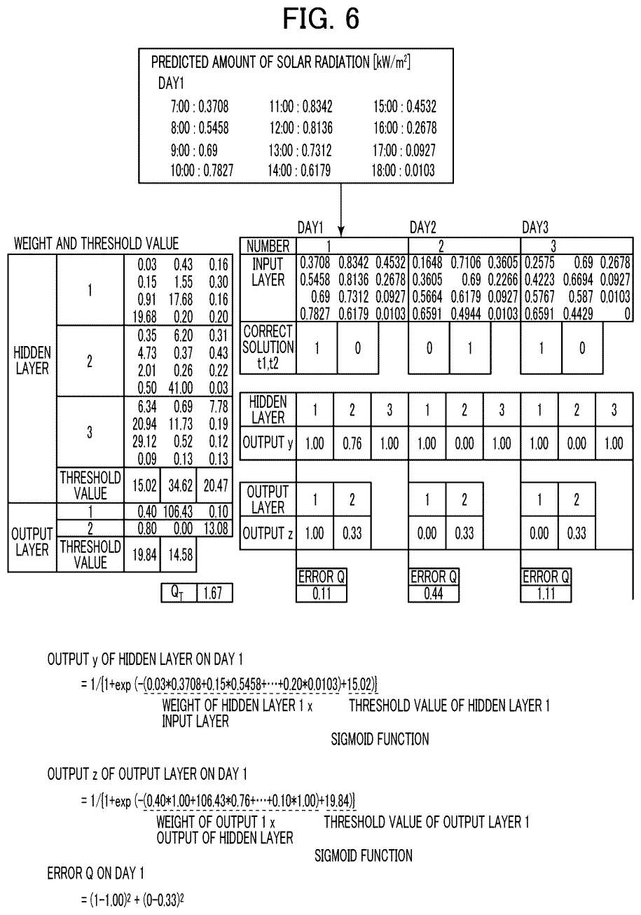

FIG. 6 is a schematic diagram showing a procedure in which a power control device 1 learns detailed weather classification. The power control device 1 can learn a correlation between the solar radiation amount prediction data and the detailed weather classification using a learning tool constructed by a neural network, for example. An example neural network is shown here in which an input layer receives solar radiation amount prediction value for twelve hours, an intermediate layer (hidden layer) is constituted by three neurons, and an output layer is constituted by two neurons.

This neural network is constructed to further classify the weather code 10 into two detailed weather classifications 11 and 12. If outputs from the two neurons of the output layer are “1” and “0”, respectively, it means that the input solar radiation amount prediction value belongs to the weather code 11. If outputs from the two neurons of the output layer are “0” and “1”, respectively, it means that the input solar radiation amount prediction value belongs to the weather code 12.

The solar radiation amount prediction value for the twelve hours on the first day (DAY 1) is input to a first neuron of the hidden layer. In this example, the weather code 11 (output layer “1” “0”) shall be the correct solution in the detailed weather classification on DAY 1. The first neuron of the hidden layer has a weighting matrix constituted by twelve elements to be multiplied by each of twelve elements in a matrix describing the solar radiation amount prediction value. The result of the multiplication of both matrices is assigned to a sigmoid function represented by a first calculation formula at the bottom of FIG. 6. A threshold value for the first neuron of the hidden layer is specified as 15.02. An output y from the first neuron of the hidden layer is calculated in the above procedure.

The solar radiation amount prediction value for the twelve hours on the first day (DAY 1) is input to a first neuron of the hidden layer. For the third and later days, a corresponding neuron of the hidden layer receives an input in a similar manner. The output y of each hidden layer is also calculated similarly. This example uses the solar radiation amount prediction to the third day is used for convenience of description, and the same applies to the fourth and later days.

The output y from the first neuron of the hidden layer is input to a first neuron of the output layer. The first neuron of the output layer has a weighting matrix constituted by three elements to be multiplied by respective outputs y of the first to third neurons of the hidden layer. The result of the multiplication of both matrices is assigned to a sigmoid function represented by a second calculation formula at the bottom of FIG. 6. A threshold value for the first neuron of the output layer is specified as 19.84. An output z from the first neuron of the output layer is calculated in the above procedure. The same applies to a second neuron of the output layer.

From the above calculations, the output from the first neuron of the output layer is 1.00 and the output from the second neuron of the output layer is 0.33. On the other hand, since the correct solution of the weather code is “1” “0”, an error Q between the output from the output layer and the correct solution can be calculated using a third calculation formula at the bottom of FIG. 6. The error Q is calculated in a similar manner for DAY 2 and DAY 3. The learning is completed by optimizing the matrix elements in each layer and the threshold values so as to minimize the error Q. A technique for optimizing the neural network such as a back propagation method is known, for example, and therefore description thereof is omitted.

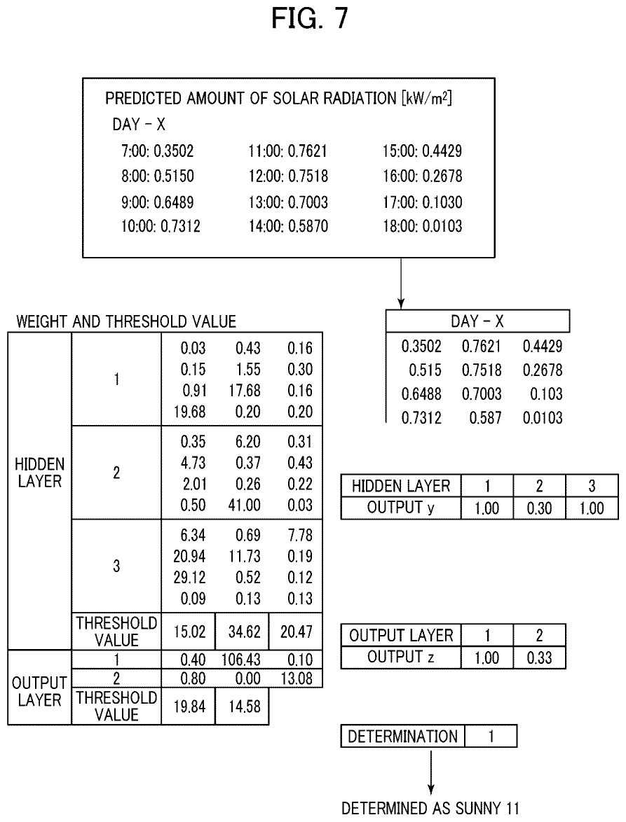

FIG. 7 illustrates a procedure of estimating the detailed weather classification using the result of learning in the procedure in FIG. 6. The power control device 1 inputs the solar radiation amount prediction data to the neural network constructed as shown in FIG. 6. An output from each neuron of the output layer is obtained in the same procedure as that for learning. For example, if the output from the first neuron of the output layer is equal to or more than threshold value and the output from the second neuron is less than the threshold value, an estimation result by the neural network is “1” “0”, namely the weather code 11. In this manner, the estimation result of the detailed weather classification can be obtained.

The power control device 1 learns in advance, for each detailed weather classification, the correlation between an assumed solar radiation amount and the solar radiation amount prediction data. The power control device 1 estimates the solar radiation amount for the solar cell using the correlation corresponding to the estimated detailed weather classification. The power control device 1 can predict the power generation amount of the solar cell using the estimated solar radiation amount. The assumed solar radiation amount can be estimated using an output current and an output voltage of the solar cell. Any known technology can be used as an estimation technique, and examples thereof include those described in Japanese Patent Application No. 2020-127908 and Japanese Patent Application No. 2021-128374.

In the following, a procedure of determining the SOC with respect to each predicted weather is described. A consignment system according to the present invention performs the consignment when the weather code is any of 11, 12, and 21. Otherwise, the consignment system performs the consignment when the weather code is either 10 or 20 throughout the consignment period. Therefore, the SOC that can secure the consignment scheduled power shall be calculated in advance for a case in which the weather code is any of those described above.

When it is predicted that the weather is stable throughout the consignment period, the weather code provided by the weather information provider is classified more finely. The case in which the weather code is any of 11, 12, and 21 corresponds to it. When it is predicted that the weather varies frequently throughout the consignment period, the weather code provided by the weather information provider is used as it is. The case in which the weather code varies between 10 and 20 corresponds to it.

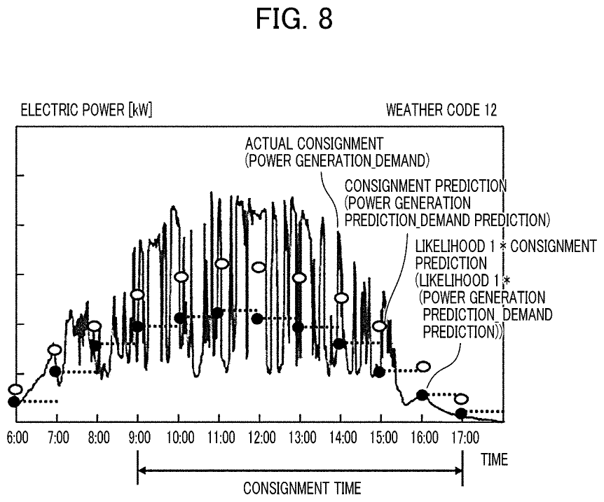

FIG. 8 is a graph comparing an actual consignment with a consignment prediction when the weather code is 12. When the weather code is 12, a variation range and a variation frequency of the solar radiation amount are larger compared to other weather codes. Accordingly, an actual power generation also varies largely and frequently. Thus, a difference between the power generation prediction and the actual power generation is also large. Therefore, when determining the charge-state of the storage battery for the weather code 12, the power control device 1 performs a processing different from that for other weather codes. Details of the processing will be described later.

As a procedure of comparing the variation range and the variation frequency of the solar radiation amount with other weather codes, for example, the following can be used. Solar radiation amount data provided by the weather information provider is described with respect to each predetermined time point. When the solar radiation amount variation range between time points is equal to or more than the threshold value, it is counted as one solar radiation amount variation, and the largest count value in the weather code corresponds to the weather code 12. Otherwise, an alternative technique may be used such as adding up absolute values of differences of the solar radiation amounts between time points throughout the consignment period. Furthermore, since the solar radiation amount corresponds to the generated power of the solar cell, the variation range or the variation frequency of the generated power may be similarly measured using generated power historical data of the solar cell with respect to each time point instead of the solar radiation amount data. The fact that the vertical axis in FIG. 8 indicates electric power is related to this.

In the present invention, a power generation instruction value to the solar cell shall be the consignment prediction multiplied by a predetermined coefficient (referred to as likelihood, ≤1.0) so that the power generating capability of the solar cell may reserve a certain degree of extra power. Accordingly, a substantial predicted consignment power is represented by consignment prediction×likelihood. In the following, the likelihood with the weather code 12 is assumed as a likelihood 1.

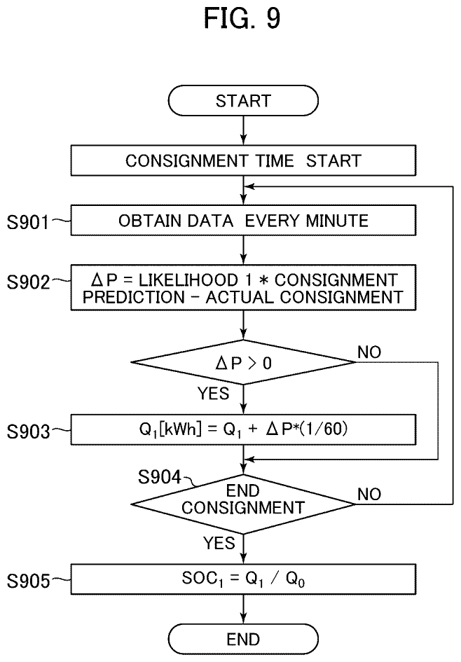

FIG. 9 is a flowchart describing a procedure of calculating an SOC that can secure consignment scheduled power with the weather code 12. This flowchart (as well as following flowcharts) can be implemented while the power control device 1 performs consignment. Each step in FIG. 9 will be described below.

### (FIG. 9: Step S901)

The power control device 1 obtains the following data during the consignment period: power generation prediction data; actual power generation data. The data is obtained with respect to each time interval (e.g., one minute) shorter than a time interval (e.g., 30 minutes) for describing the consignment schedule in the consignment period.

### (FIG. 9: Step S902)

The power control device 1 multiplies the consignment prediction by the likelihood 1 and subtracts the actual consignment from the result. The calculation result is stored as ΔP. The consignment prediction is obtained by subtracting the demand prediction from the power generation amount prediction of the solar cell. The actual consignment is obtained by subtracting an actual demand from the actual power generation of the solar cell. The process proceeds to S903 if the ΔP is larger than 0, and otherwise skips to S904.

### (FIG. 9: Step S903)

The power control device 1 adds the ΔP multiplied by the time interval (one minute in this example) at S901 to Q1 [kWh]. An initial value of Q1 is 0. When the ΔP is positive, it means that the actual consignment is smaller than the consignment prediction, and therefore it is required to retain electric power that can secure the consignment scheduled power in the storage battery by discharging the storage battery. Q1 is equivalent to an amount of the power.

### (FIG. 9: Step S904)

The power control device 1 performs S901 to S903 repeatedly until the consignment period ends.

### (FIG. 9: Step S905)

The power control device 1 calculates a ratio of Q1 with respect to a full charge capacity Q0 [kWh] of the storage battery (Q1/Q0) as a charge-state SOC1 that the storage battery needs to secure with the weather code 12. It is conceived that the consignment scheduled power in the consignment period can be secured by the storage battery securing the SOC1 in advance at a subsequent starting point of the consignment period in which the weather code is 12.

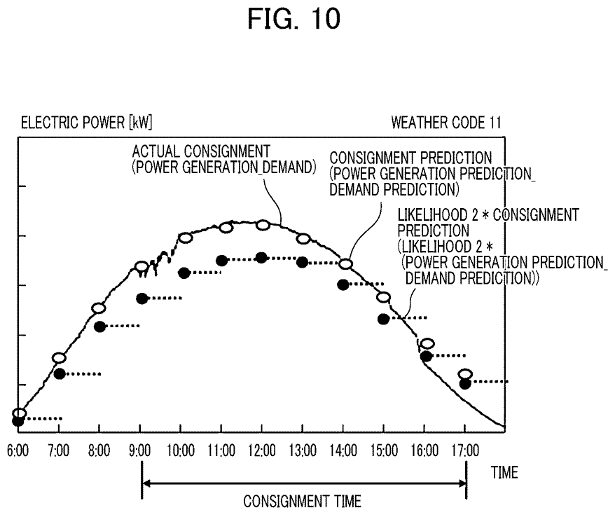

FIG. 10 is a graph comparing an actual consignment with a consignment prediction when the weather code is 11. When the weather code is 11, both the variation range and the variation frequency of the solar radiation amount are smaller than those with the weather code 12. The likelihood with the weather code 11 is assumed as a likelihood 2.

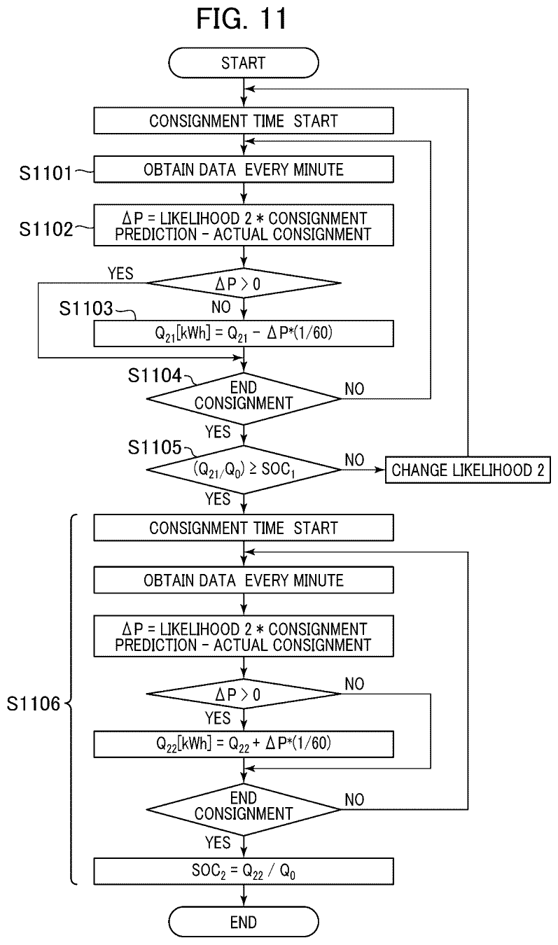

FIG. 11 is a flowchart describing a procedure of calculating an SOC that can secure consignment scheduled power with the weather code 11 Each step in FIG. 11 will be described below.

### (FIG. 11: Step S1101 to Step S1102)

These steps are similar to S901 to S902. The process skips to S1104 if the ΔP is larger than 0, and otherwise proceeds to S1103.

### (FIG. 11: Step S1103)

The power control device 1 subtracts the ΔP multiplied by the time interval (one minute in this example) at S1101 from Q21 [kWh]. An initial value of Q21 is 0. When the ΔP is negative, it means that the actual consignment is larger than the consignment prediction, and therefore its surplus power can be charged to the storage battery. Q21 is equivalent to an amount of the power.

### (FIG. 11: Step S1104)

The power control device 1 performs S1101 to S1103 repeatedly until the consignment period ends.

### (FIG. 11: Step S1105)

The power control device 1 calculates a ratio of Q21 with respect to the full charge capacity Q0 [kWh] of the storage battery (Q21/Q0). This is equivalent to the SOC that the storage battery can charge with a current likelihood 2. When the calculation result is less than the SOC1, the likelihood 2 is changed and the process returns to S1101. That is, the likelihood 2 is searched for that realizes the SOC1 that can secure the consignment scheduled power with the weather code 12.

### (FIG. 11: Step S1106)

The power control device 1 calculates a charge-state SOC2 to be secured by the storage battery with the weather code 11 according to a procedure similar to that in FIG. 9.

### (FIG. 11: Step S1106: Supplement 1)

At S1101 to S1105, the likelihood 2 is defined so that the charge-state is equal to or more than the SOC1 by charging the storage battery when the actual power generation is above the power generation prediction. Furthermore, at S1106, the charge-state SOC2 is calculated that is required for discharging from the storage battery when the actual power generation is equal to or less than the power generation prediction. Accordingly, the storage battery should be charged with the SOC1 or more at a time interval (every minute) in which the actual power generation is above the power generation prediction, and should secure the SOC2 or more at a time interval in which the actual power generation is below the power generation prediction. As a result, the charge-state of the storage battery with the weather code 11 is SOC1+SOC2 at most (or even higher depending on the actual value) at the end time of the consignment period. This is because the SOC1 or more is further secured if there is still surplus power after securing the SOC2 in advance in preparation for power shortage. During the later consignment periods in which the weather code is 11, it is conceived that the consignment scheduled power can be secured by the storage battery securing the SOC2 in advance at the start time and securing the SOC1+SOC2 at most (or even more) at the end time.

### (FIG. 11: Step S1106: Supplement 2)

The charge-state required at the starting point with the weather code 11 is the SOC2. In addition, even if the weather code is 12 in the next consignment period, it is desired that the SOC1 should be secured at the starting point. Then, if all the SOC2 is used up in the consignment period with the weather code 11, in order to secure the SOC1 at the start of the next consignment period with the weather code 12, it is required to charge the SOC1 in addition to the SOC2. Thus, SOC1+SOC2 is secured at the starting point of the next consignment period if the storage battery is not used at all with the weather code 11, and the SOC1 is secured at the starting point of the next consignment period if the storage battery is used up. That is, the charge-state at the end point with the weather code 12 is at least SOC1 and at most SOC1+SOC2 (or even more).

### (FIG. 11: Step S1106: Supplement 3)

At least SOC1 is secured at the end point with the weather code 12 because the accuracy of the weather prediction is not necessarily high. Therefore, first half of the steps in FIG. 11 are performed to be able to secure the SOC1 at the starting point of the consignment period regardless of what the actual weather code is.

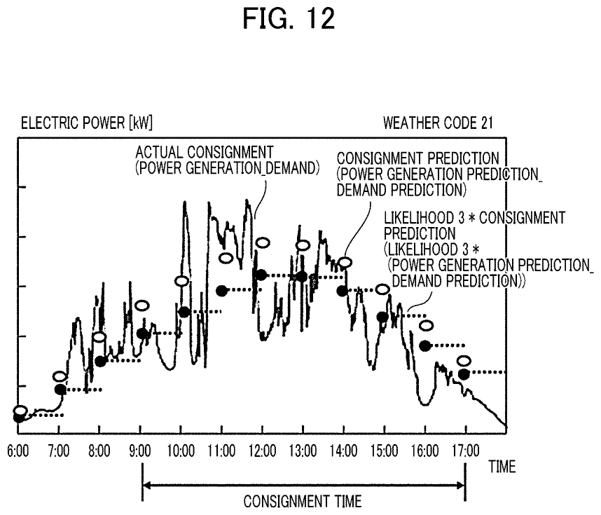

FIG. 12 is a graph comparing an actual consignment with a consignment prediction when the weather code is 21. When the weather code is 21, both the variation range and the variation frequency of the solar radiation amount are smaller than those with the weather code 12 and larger than those with the weather code 11. The likelihood with the weather code 21 is assumed as a likelihood 3.

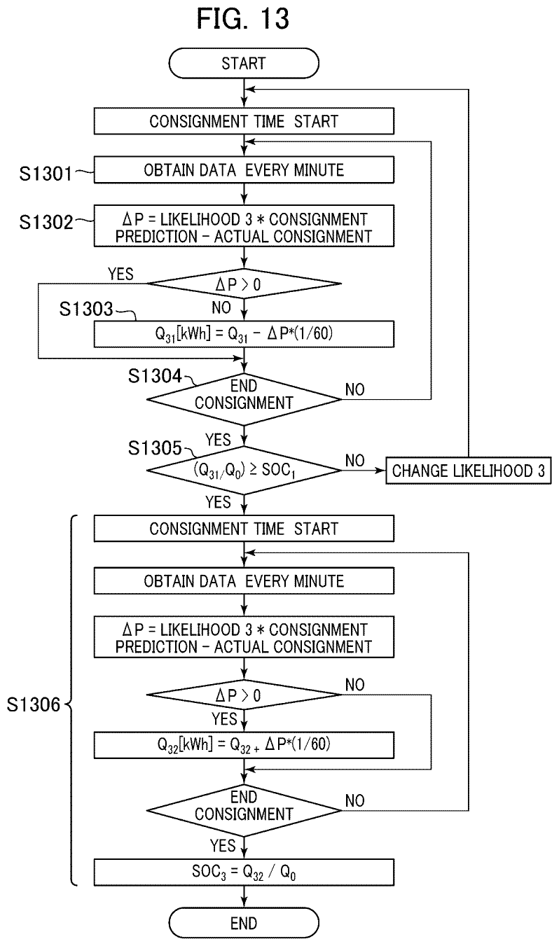

FIG. 13 is a flowchart describing a procedure of calculating an SOC that can secure consignment scheduled power with the weather code 21. FIG. 13 is similar to FIG. 11 except that the likelihood 3 is used, and therefore details thereof are not described. During the later consignment periods in which the weather code is 21, it is conceived that the consignment scheduled power can be secured by the storage battery securing the SOC3 in advance at the start time and securing the SOC1+SOC3 at most (or even more) at the end time.

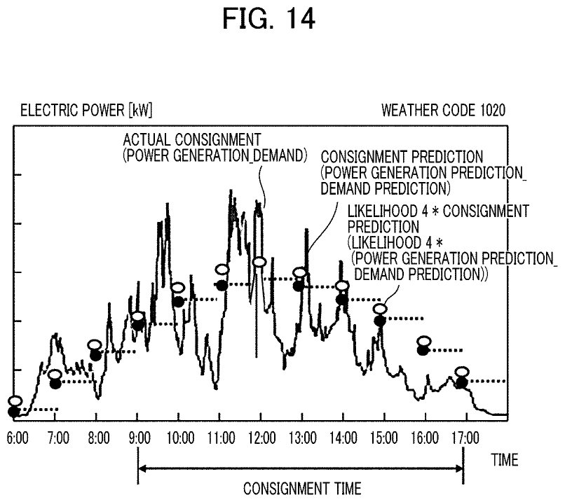

FIG. 14 is a graph comparing an actual consignment with a consignment prediction when the weather code is 10 or 20. When the weather code is 10 or 20, both the variation range and the variation frequency of the solar radiation amount are smaller than those with the weather code 12 and larger than those with the weather code 11. The likelihood with the weather code 10 or 20 is assumed as a likelihood 4.

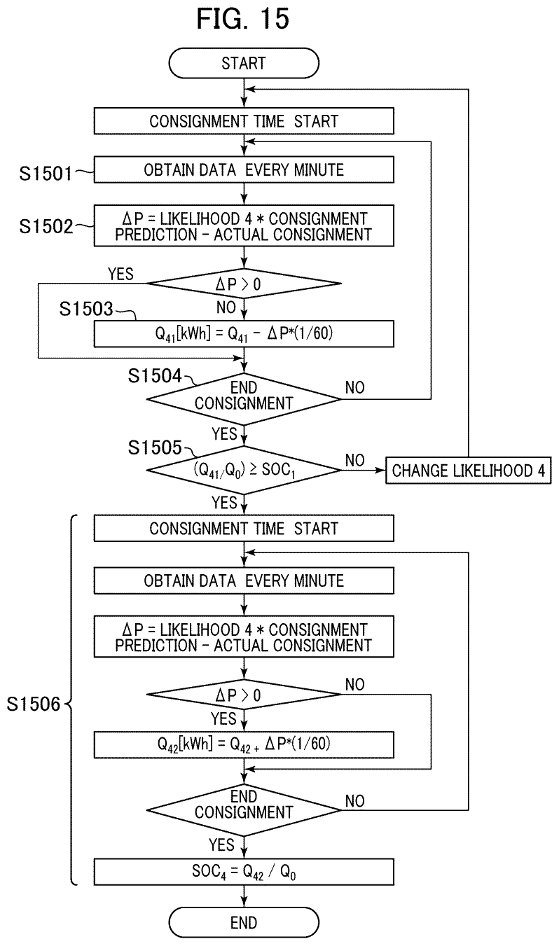

FIG. 15 is a flowchart describing a procedure of calculating an SOC that can secure consignment scheduled power with the weather code 10 or 20. FIG. 15 is similar to FIG. 11 except that the likelihood 4 is used, and therefore details thereof are not described. During the later consignment periods in which the weather code is 10 or 20, it is conceived that the consignment scheduled power can be secured by the storage battery securing the SOC4 in advance at the start time and securing the SOC1+SOC4 at most (or even more) at the end time.

FIGS. 8 to 15 show examples in which the variation range and the variation frequency of the solar radiation amount when the weather code is 12 are larger than those with other weather codes. This is an illustration in view of consideration that such a solar radiation amount variation may be feasible when the weather is between sunny and cloudy. However, the present invention is not limited thereto but the power control device 1 may obtain a history of the solar radiation amount (or a power generation history of the solar cell) with respect to each weather code and specify the largest variation range and the largest variation frequency of the solar radiation amount among the weather codes. Otherwise, the result specified in advance may be used as in the above-described embodiments.

### Second Embodiment

The power control device 1 described in the first embodiment can include the computing unit 11 that performs the operations described with reference to FIGS. 4 to 15. The computing unit 11 can be configured using hardware such as a circuit device implementing its functions or can be configured by an arithmetic unit implementing its functions. The power control device 1 can further include the memory unit 12 that stores therein a history of each of the data described in the first embodiment (such as power generation amount prediction data, demand data, demand prediction data, and the like).

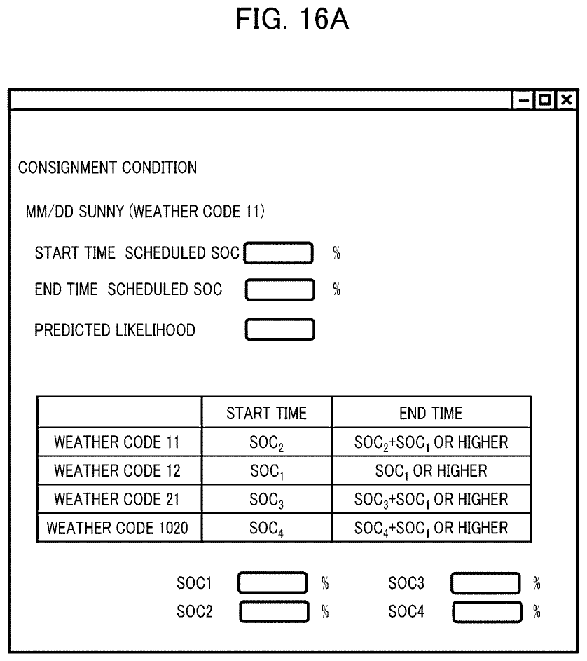

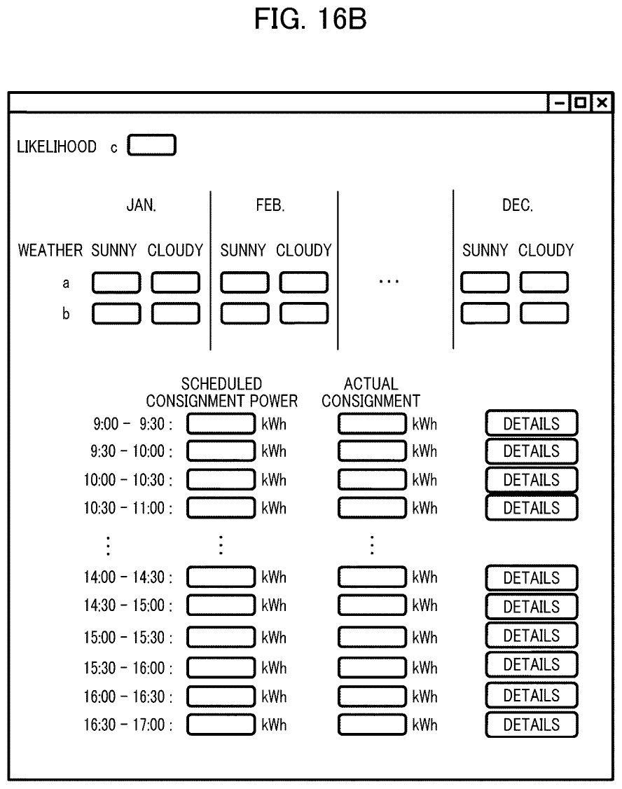

FIGS. 16A and 16B show an example of a user interface provided by the power control device 1. The user interface can be presented by the computing unit 11 on a display device such as a display. The user interface can display, for example, the charge-state to be secured by the storage battery at the start time and the end time of the consignment period for each weather code (FIG. 16A). Furthermore, the user interface can display respective numerical values of the consignment scheduled power and the actual consignment for each consignment period (FIG. 16B).

### Modification of Present Invention

The present invention is not limited to the above-described embodiments, and further includes various modifications. For example, the above-described embodiments have been described in detail in order to facilitate the understanding of the present invention, and the present invention is not necessarily limited to those including all of the described configurations. In addition, part of the configuration of one example can be replaced with the configurations of other embodiments, and in addition, the configuration of the one embodiments can also be added with the configurations of other embodiments. In addition, part of the configuration of each of the embodiments can be subjected to addition, deletion, and replacement with respect to other configurations.

While the procedure has been described in the above embodiments, in which the power control device 1 (computing unit 11) determines the charge-state of the storage battery and the likelihood, the storage battery may be further controlled by indicating the determined charge-state to the storage battery or the power generation amount of the solar cell may be further controlled using the determined likelihood. The control can be performed, for example, via an instruction to the driving device (e.g., converter) that drives the storage battery or the solar cell.

### LIST OF REFERENCE SIGNS

1: power control device
11: computing unit
12: memory unit

1. A charge-state calculation device that calculates a charge-state to be secured by a storage battery when transmitting power generated by a power generation system constituted by a solar cell and the storage battery between bases via a power transmission network, comprising:
a computing unit that calculates the charge-state,
wherein the computing unit obtains an actual power generation by the solar cell with respect to each predetermined time point in a power transmission period with respect to each value of weather codes describing a result of predicting a weather type during the power transmission period in which power transmission is performed between the bases, and
wherein the computing unit determines the charge-state of the storage battery so as to compensate for shortage of an actual power generation amount with discharge from the storage battery even if the actual power generation amount actually generated by the solar cell is less than a predicted power generation amount of the solar cell during a first power transmission period in which a first weather is predicted among the weather codes, the first weather indicating the weather code in which a variation range with respect to each predetermined time point of the actual power generation exceeds a threshold value most frequently.

2. The charge-state calculation device according to claim 1,
wherein the computing unit obtains a first predicted power that was predicted to be output to the power transmission network during the first power transmission period,
wherein the computing unit obtains a first actual power actually output to the power transmission network during the first power transmission period,
wherein the computing unit calculates a first difference between a first corrected predicted power obtained by applying a first correction factor to the first predicted power and the first actual power,
wherein the computing unit calculates a first amount of power obtained by multiplying a time interval divided from the first power transmission period by the first difference when the first corrected predicted power is larger than the first actual power, and
wherein the computing unit determines the charge-state according to the calculated first amount of power.

3. The charge-state calculation device according to claim 2,
wherein the computing unit obtains the first predicted power with respect to each time interval and the first actual power with respect to each time interval, respectively, and
wherein the computing unit determines the charge-state so as to compensate by the storage battery for the shortage at a subsequent starting point of the power transmission period for which the first weather is predicted, by calculating the first amount of power from a time point at which the first power transmission period starts to a time point at which the first power transmission period ends with respect to each time interval and also by adding up a calculation result thereof with respect to each time interval.

4. The charge-state calculation device according to claim 1,
wherein the computing unit determines the power generation amount of the solar cell throughout a second power transmission period so that a remaining capacity more than the determined charge-state is secured at an end point of the power transmission period for the second power transmission period for which a second weather different from the first weather is predicted.

5. The charge-state calculation device according to claim 4,
wherein the computing unit obtains a second predicted power predicted to be output to the power transmission network during the second power transmission period,
wherein the computing unit obtains a second actual power actually output to the power transmission network during the second power transmission period,
wherein the computing unit calculates a second difference between a second corrected predicted power obtained by applying a second correction factor to the second predicted power and the second actual power,
wherein the computing unit calculates a second amount of power obtained by multiplying a time interval divided from the second power transmission period by the second difference when the second corrected predicted power is smaller than the second actual power,
wherein the computing unit determines the second correction factor so that the calculated second amount of power can secure the remaining capacity, and
wherein the computing unit controls the solar cell so as to generate the second corrected predicted power to which the determined second correction factor is applied.

6. The charge-state calculation device according to claim 5,
wherein the computing unit obtains a third predicted power predicted to be output to the power transmission network during the second power transmission period,
wherein the computing unit obtains a third actual power actually output to the power transmission network during the second power transmission period,
wherein the computing unit calculates a third difference between a third corrected predicted power obtained by applying the determined second correction factor to the second predicted power and the third actual power,
wherein the computing unit calculates a third amount of power obtained by multiplying a time interval divided from the second power transmission period by the third difference when the third corrected predicted power is larger than the third actual power, and
wherein the computing unit determines the charge-state according to the calculated third amount of power.

7. The charge-state calculation device according to claim 6,
wherein the computing unit obtains the third predicted power with respect to each time interval and the third actual power with respect to each time interval, respectively, and
wherein the computing unit determines the charge-state so as to compensate by the storage battery for the shortage at a subsequent starting point of the power transmission period for which the second weather is predicted, by calculating the third amount of power calculated using the determined second correction factor with respect to each time interval from a time point at which the second power transmission period starts to a time point at which the second power transmission period ends and also by adding up a calculation result thereof with respect to each time interval.

8. The charge-state calculation device according to claim 5,
wherein, at the starting point of the second power transmission period, the computing unit determines the charge-state so as to compensate by the storage battery for the shortage at a subsequent starting point of the power transmission period for which the second weather is predicted,
wherein, at the end point of the second power transmission period, the computing unit determines the charge-state so as to secure at least the charge-state determined for the first power transmission period, and
wherein, at the end point of the second power transmission period, the computing unit determines the charge-state so as to secure a charge-state including at most
the charge-state determined for the first power transmission period and
the charge-state of which shortage can be compensated by the storage battery at a subsequent starting point of the power transmission period for which the second weather is predicted
added up together.

9. The charge-state calculation device according to claim 1,
wherein the computing unit obtains prediction data describing a result of predicting a solar radiation amount based on weather information,
wherein the computing unit calculates a first prediction value of the solar radiation amount using an output current from the solar cell and an output voltage from the solar cell,
wherein the computing unit obtains a second prediction value of the solar radiation amount described in the prediction data,
wherein the computing unit learns a correlation between the first prediction value and the second prediction value in advance,
wherein the computing unit estimates the solar radiation amount by fitting the prediction value described in the prediction data into the correlation obtained as a result of the learning, and
wherein the computing unit predicts the power generation amount of the solar cell using the solar radiation amount estimated using the correlation.

10. The charge-state calculation device according to claim 9,
wherein the computing unit learns the correlation with respect to each detailed weather code for which the weather code is further classified,
wherein the computing unit estimates the detailed weather code by applying the prediction value described in the prediction data to the correlation learned with respect to each detailed weather code, and
wherein the computing unit estimates the solar radiation amount by fitting the prediction value described in the prediction data into the correlation corresponding to the estimated detailed weather code.

11. The charge-state calculation device according to claim 1,
wherein the computing unit outputs a user interface, and
wherein the user interface is configured to present the charge-state determined for both the start time and the end time of the power transmission period, respectively.
